(19) United States
(12) Patent Application Publication
(10) Pub. No.: US 2026/0198290 A1
(43) Pub. Date: Jul. 9, 2026

(54) POWER PLANE BETWEEN STACKED FETS

(71) Applicant: INTERNATIONAL BUSINESS MACHINES CORPORATION, Armonk, NY (US)

(72) Inventors: Shay Reboh, Albany, NY (US); Utkarsh Bajpai, Suffern, NY (US); James Patrick Mazza, Saratoga Springs, NY (US); Nicholas Anthony Lanzillo, Wynantskill, NY (US); Tenko Yamashita, Schenectady, NY (US); Huiming Bu, Glenmont, NY (US)

(21) Appl. No.: 19/013,738

(22) Filed: Jan. 8, 2025

(51) Int. Cl. H01L 23/528; H01L 23/522; H10D 84/83

(52) U.S. Cl. CPC H10W 20/427; H10D 84/83; H10W 20/42; H10W 20/435

(57) ABSTRACT

Embodiments of present invention provide a semiconductor structure. The semiconductor structure includes a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to the first transistor cell; and at least one power plane between the first top transistor and the first bottom transistor and between the second top transistor and the second bottom transistor. A method of forming the same is also provided.

### BACKGROUND

The present application relates to structure of semiconductor integrated circuits. More particularly, it relates to stacked field-effect-transistors with power delivery plane in-between and method of forming the same.

As semiconductor industry moves towards smaller node, field-effect-transistors (FETs) are aggressively scaled to fit into reduced footprint or real estate that is dictated by the node size. For example, FETs may be formed in layers and different layers of FETs may be stacked one on top of another to increase overall density of the device. With vertically stacked FETs, power supply or delivery to the various FETs at the top and the bottom layers becomes an important consideration during the device design.

### SUMMARY

Embodiments of present invention provide a semiconductor structure. The semiconductor structure includes a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to the first transistor cell; and at least one power plane between the first top transistor and the first bottom transistor and between the second top transistor and the second bottom transistor.

According to one embodiment, the at least one power plane is a first power plane, and the semiconductor structure further includes a second power plane underneath the first power plane and between the second top transistor and the second bottom transistor, the second power plane being parallel to the first power plane.

According to another embodiment, the semiconductor structure further includes a through-power-plane-via (TPPV) extending vertically through the first and the second power plane, from a level above the second top transistor to a level below the second bottom transistor, the TPPV being insulated from the first and the second power plane by a sidewall spacer.

In one embodiment, the second top transistor do not vertically align with the second bottom transistor and the TPPV is formed within the second transistor cell but away from the second top transistor and away from the second bottom transistor.

In one embodiment, the first top transistor is conductively connected to the first power plane by a power via.

In another embodiment, the first top transistor is conductively connected to the second power plane by a power via, and the power via extends through an opening in the first power plane and is insulated from the first power plane by a sidewall spacer.

In yet another embodiment, the first top transistor is conductively connected to the first bottom transistor by a power via, and the power via extends through an opening in the first power plane and through an opening in the second power plane and is insulated from the first and the second power plane by a sidewall spacer.

According to one embodiment, the semiconductor structure further includes a middle dielectric layer between the first power plane and the second power plane, and the middle dielectric layer insulates the first power plane from the second power plane.

According to another embodiment, the semiconductor structure further includes a top dielectric plane directly on top of the first power plane and underneath the first and the second top transistor.

According to yet another embodiment, the semiconductor structure further includes a bottom dielectric plane on top of the first and the second bottom transistor and directly underneath the first power plane.

Embodiments of present invention further provide a semiconductor structure. The semiconductor structure includes a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to a first side of the first transistor cell; a third stack of transistors in a third transistor cell, the third stack of transistors including a third top transistor and a third bottom transistor, the third transistor cell being adjacent to a second side of the first transistor cell, the second side opposing the first side; a first power plane between the first top transistor and the first bottom transistor and between the second top transistor and the second bottom transistor; and a second power plane between the first top transistor and the first bottom transistor and between the third top transistor and the third bottom transistor, where the second bottom transistor is underneath the first power plane and the third top transistor is above the second power plane.

In one embodiment, the first and the second power plane vertically overlap in the first transistor cell and do not vertically overlap in the second and third transistor cell.

In another embodiment, the first and the second power plane horizontally extend across the first, the second, and the third transistor cell.

Embodiments of present invention yet provide a semiconductor structure. The semiconductor structure includes a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to the first transistor cell; a third stack of transistors in a third transistor cell, the third stack of transistors including a third top transistor and a third bottom transistor, the third transistor cell being adjacent to the first transistor cell; a first power plane between the first top transistor and the first bottom transistor and between the second top transistor and the second bottom transistor; and a second power plane between the first top transistor and the first bottom transistor and between the third top transistor and the third bottom transistor.

According to one embodiment, the semiconductor structure further includes a middle dielectric plane between the first power plane and the second power plane, where the first and the second power plane vertically overlap at least in the first transistor cell.

In one embodiment, the first power plane is connected to a VDD and the second power plane is connected to a VSS of a static-random-access memory (SRAM) device.

In one embodiment, the first power plane is connected to a back-end-of-line (BEOL) structure above the first and the second top transistor through a first routing via at a boundary between the first transistor cell and the third transistor cell.

In another embodiment, the second power plane is connected to a backside back-end-of-line (BBEOL) structure below the first and the third bottom transistor through a second routing via at a boundary between the first transistor cell and the second transistor cell.

In one embodiment, a source/drain region of the first top transistor is conductively connected to a source/drain region of the first bottom transistor through a through-power-plane-via (TPPV), the TPPV has a bottom portion and a top portion on top of the bottom portion and a sidewall that changes discontinuously from the bottom portion to the top portion.

In another embodiment, a source/drain region of the second top transistor is conductively connected to the first power plane by a power via.

### BRIEF DESCRIPTION OF THE DRAWINGS

The present invention will be understood and appreciated more fully from the following detailed description of embodiments of present invention, taken in conjunction with accompanying drawings of which:

FIG. 1A is a demonstrative top view and FIG. 1B is a demonstrative cross-sectional view of a semiconductor structure with stacked field-effect-transistors according to one embodiment of present invention;

FIG. 2A is a demonstrative top view and FIG. 2B is a demonstrative cross-sectional view of a semiconductor structure with stacked field-effect-transistors according to another embodiment of present invention;

FIG. 3A is a demonstrative top view and FIG. 3B is a demonstrative cross-sectional view of a semiconductor structure with stacked field-effect-transistors according to yet another embodiment of present invention;

FIG. 4A is a demonstrative top view and FIG. 4B is a demonstrative cross-sectional view of a semiconductor structure with stacked field-effect-transistors according to a further embodiment of present invention;

FIGS. 5-10 are demonstrative illustrations of cross-sectional views of a semiconductor structure at various steps of manufacturing thereof according to embodiments of present invention; and

FIG. 11 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

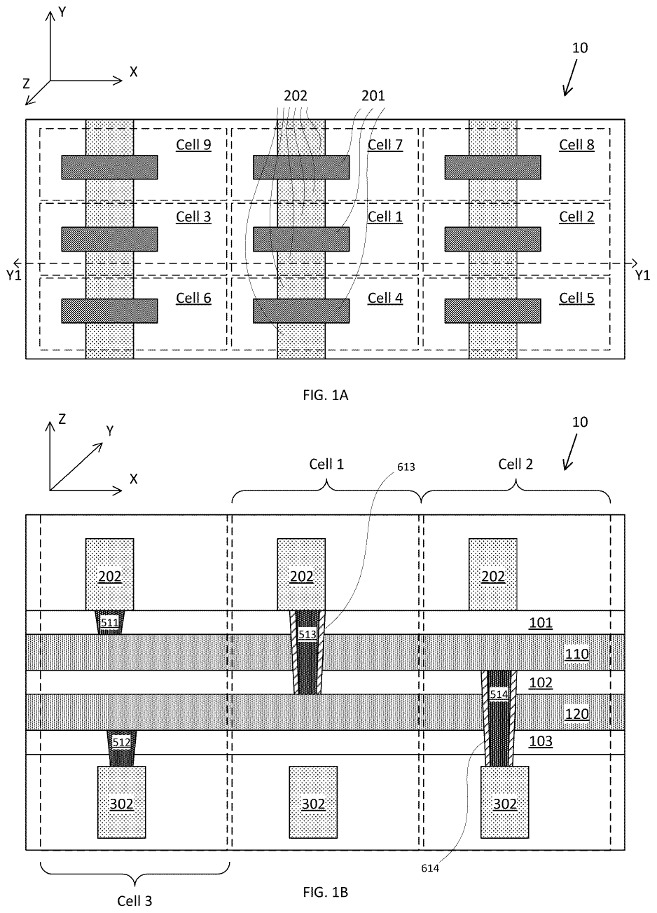

FIG. 1A is a demonstrative illustration of a simplified top view and FIG. 1B is a demonstrative illustration of a cross-sectional view of a semiconductor structure according to one embodiment of present invention. More specifically, FIG. 1B illustrates a cross-sectional view of the semiconductor structure with a cross-section made along a dashed line Y1-Y1 as being indicated in FIG. 1A. In other words, the cross-section illustrated in FIG. 1B is made across source/drain (S/D) regions of transistors in transistor cells 1, 2, and 3 in a direction along width of gates of the transistors. As a simplified top view, FIG. 1A illustrates the location of the cross-section by the dashed line Y1-Y1, and only key elements of the semiconductor structure such as, for example, gates and S/D regions of the transistors. Other elements such as dielectric cap layer, sidewall spacers, etc. are not necessarily illustrated in FIG. 1A for brevity and clarity, and to the extent that their omission from FIG. 1A does not hinder the description of embodiments of present invention.

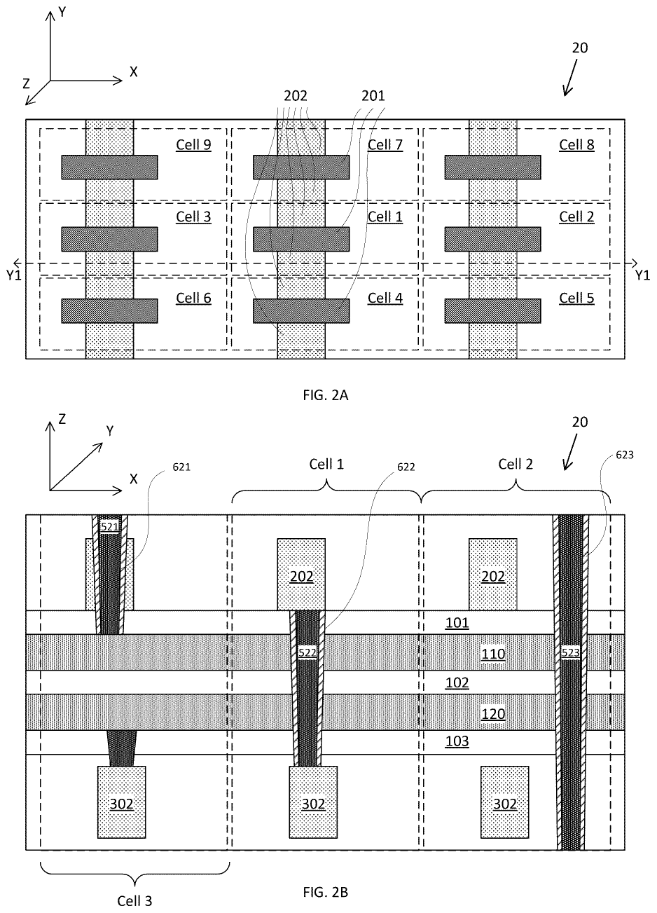

Likewise, FIGS. 2A, 3A, and 4A are demonstrative illustrations of simplified top views and FIGS. 2B, 3B, and 4B are demonstrative illustrations of cross-sectional views of several semiconductor structures according to various embodiments of present invention.

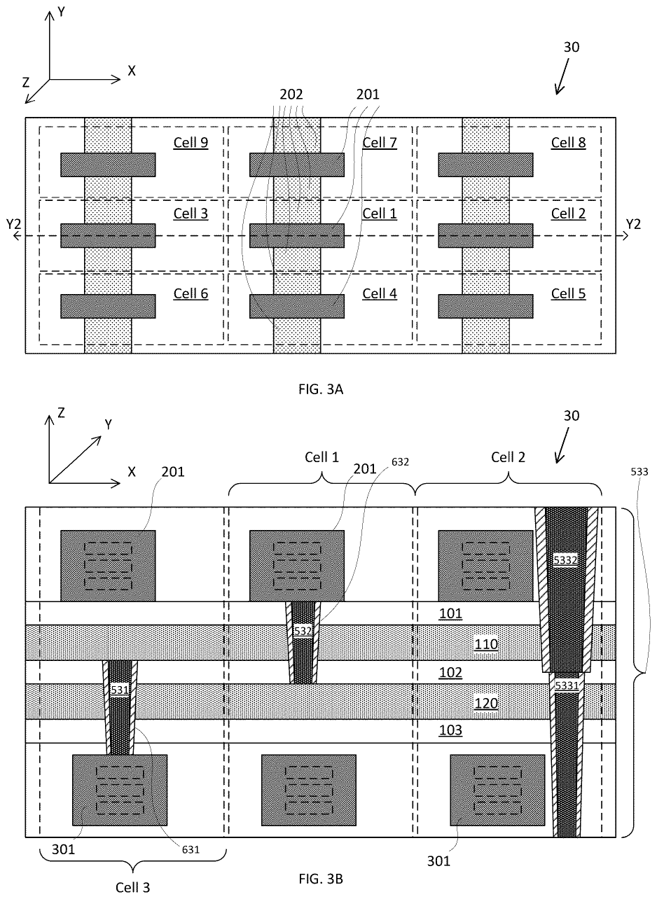

More particularly, embodiments of present invention provide a semiconductor structure 10 as is illustrated in FIG. 1A that includes a plurality of transistor cells, such as transistor cells 1, 2, 3, 4, 5, 6, 7, 8, and 9 that each includes a stack of transistors such as a stack of field-effect-transistors (FETs). In one embodiment, transistor cells 1, 2, and 3, transistor cells 4, 5, and 6, and transistor cells 7, 8, and 9 may be substantially and respectively aligned along the x-direction. In another embodiment, transistor cells 1, 4, and 7, transistor cells 2, 5, and 8, and transistor cells 3, 6, and 9 may be substantially and respectively aligned along the y-direction. Each stack of transistors are stacked in the z-direction with a top transistor on top of a bottom transistor. The top transistor of each stack of transistors may include a gate 201 between a pair of S/D regions 202 and the bottom transistor of each stack of transistors may include a gate 301 (see FIG. 3B) between a pair of S/D regions 302. In one embodiment, a stack of transistors may include dummy transistors, and a dummy transistor may or may not have dummy S/D regions.

For example, as is illustrated in FIG. 1B, the semiconductor structure 10 may include a first stack of transistors in a first transistor cell 1. The first stack of transistors includes a first top transistor and a first bottom transistor. Similarly, the semiconductor structure 10 may include a second stack of transistors in a second transistor cell 2. The second stack of transistors may include a second top transistor and a second bottom transistor. The semiconductor structure 10 may further include a third stack of transistors in a third transistor cell 3 that includes a third top transistor and a third bottom transistor. The first, second, and third top transistors may each have a source/drain (S/D) region 202 and the first, second, and third bottom transistors may each have a S/D region 302.

The semiconductor structure 10 may further include at least a first power plane 110 between the first top transistor and the first bottom transistor in the first transistor cell 1. The first power plane 110 may also be between the second top transistor and the second bottom transistor in the second transistor cell 2, with the second transistor cell 2 being adjacent to the first transistor cell 1 at a first side thereof. In other words, the first power plane 110 expands across at least two adjacent transistor cells. As is illustrated in FIG. 1B, the semiconductor structure 10 may further include a second power plane 120 directly underneath the first power plane 110 and between at least the first top transistor and the first bottom transistor in the first transistor cell 1 and between the third top transistor and the third bottom transistor in the third transistor cell 3, with the third transistor cell 3 being adjacent to the first transistor cell 1 at a second side thereof with the second side opposing the first side. The second power plane 120 may be parallel to the first power plane 110 and may be separated and/or insulated from the first power plane 110 by a middle dielectric plane 102. The middle dielectric plane 102 may be a layer of dielectric material and thus a dielectric layer.

In one embodiment, the semiconductor structure 10 may further include a top dielectric plane 101 on top of the first power plane 110 and underneath, for example, the first and second top transistors of the first and second transistor cells 1 and 2. In another embodiment, the semiconductor structure 10 may also include a bottom dielectric plane 103 underneath the second power plane 120 but above, for example, the first and second bottom transistors of the first and second transistor cells 1 and 2.

In one embodiment, the S/D region 202 of a top transistor such as the third top transistor in the third transistor cell 3 may be directly and conductively connected to the first power plane 110 through a power via 511. The S/D region 302 of a bottom transistor such as the third bottom transistor in the third transistor cell 3 maybe directly and conductively connected to the second power plane 120 through a power via 512, where the second power plane 120 may be underneath the first power plane 110. In another embodiment, the S/D region 202 of a top transistor such as the first top transistor in the first transistor cell 1 may be conductively connected to the second power plane 120 through a through-power-plane-via (TPPV) 513. Extending vertically through the first power plane 110, via an opening made in the first power plane 110, the TPPV 513 may be insulated from the first power plane 110 by a sidewall spacer 613. In one embodiment, the sidewall spacer 613 is a dielectric liner made of, for example, silicon-oxide, silicon-nitride, or other suitable insulating materials. In another embodiment, the S/D region 302 of a bottom transistor such as the second bottom transistor in the second transistor cell 2 may be conductively connected to the first power plane 110 through a TPPV 514. Extending vertically through the second power plane 120, via an opening made in the second power plane 120, the TPPV 514 may be insulated from the second power plane 120 by a sidewall spacer 614 such as a dielectric liner.

FIG. 2A is a demonstrative illustration of a simplified top view and FIG. 2B is a demonstrative illustration of a cross-sectional view of a semiconductor structure 20 according to another embodiment of present invention. More specifically, FIG. 2B illustrates a cross-sectional view of the semiconductor structure 20 with a cross-section made along a dashed line Y1-Y1, as being indicated in FIG. 2A, across S/D regions of transistors in transistor cells 1, 2, and 3 in a direction along width of gate of the transistors. Similar to the semiconductor structure 10, the semiconductor structure 20 includes a first power plane 110 and a second power plane 120 between a set of top transistors and a set of bottom transistors of transistor cells 1, 2, and 3.

In one embodiment, the semiconductor structure 20 may include a power via 521, formed through a S/D region 202 of a top transistor of the third transistor cell 3. The power via 521 is conductively connected to the first power plane 110. Being insulated from the S/D region 202 by a sidewall spacer 621, the power via 521 may be formed to connect a device or metal line of a back-end-of-line (BEOL) (not shown) above the top transistor of the third transistor cell 3 to the first power plane 110. In another embodiment, formed in the first transistor cell 1, the semiconductor structure 20 may include a TPPV 522 that conductively connects the S/D region 202 of the first top transistor to the S/D region 302 of the first bottom transistor of the first transistor cell 1. The TPPV 522 may vertically extend through both the first and the second power plane 110 and 120, via openings made therein, and be insulated from the first and the second power plane 110 and 120 by a sidewall spacer 622, or a dielectric liner, of some dielectric insulating material. In yet another embodiment, the semiconductor structure 20 may include a TPPV 523 that extends vertically through the first and the second power plane 110 and 120, from a level above the second top transistor to a level below the second bottom transistor in the second transistor cell 2. The TPPV 523 may be insulated from the first and the second power plane 110 and 120 by a sidewall spacer 623 or dielectric liner as well, may be away from the S/D region 202 of the top transistor and away from the S/D region 302 of the bottom transistor in the transistor cell 2.

As being demonstratively illustrated in FIG. 2B, the top transistors, being stacked on top of the bottom transistors, may not necessarily be vertically aligned with the bottom transistors. For example, S/D regions 202 of the top transistors may not necessarily be vertically aligned with S/D regions 302 of the bottom transistors. As being demonstratively illustrated later in FIG. 3B, gates of the top transistors may not necessarily be vertically aligned with gates of the bottom transistors.

FIG. 3A is a demonstrative illustration of a simplified top view and FIG. 3B is a demonstrative illustration of a cross-sectional view of a semiconductor structure 30 according to yet another embodiment of present invention. More specifically, FIG. 3B illustrates a cross-sectional view of the semiconductor structure 30 with a cross-section made along a dashed line Y2-Y2, as being indicated in FIG. 3A, across gates of transistors and along width of the gates of the transistors in transistor cells 1, 2, and 3. Similar to the semiconductor structures 10 and 20, the semiconductor structure 30 includes a first power plane 110 and a second power plane 120 between a set of top transistors and a set of bottom transistors of transistor cells 1, 2, and 3.

In one embodiment, the gate 301 of a bottom transistor such as the third bottom transistor in the third transistor cell 3 may be conductively connected to the first power plane 110 through a TPPV 531, such as when the first power plane 110 is used as a signal routing plane, other than as a power supply. Extending vertically through the second power plane 120, via an opening made in the second power plane 120, the TPPV 531 may be insulated from the second power plane 120 by a sidewall spacer 631, or a dielectric liner, of dielectric material. In another embodiment, the gate 201 of a top transistor such as the first top transistor in the first transistor cell 1 may be conductively connected to the second power plane 120 through a TPPV 532 such as in situations when the second power plane 120 is used as a signal routing plane, other than as a power supply. Extending vertically through the first power plane 110, via an opening made in the first power plane 110, the TPPV 532 may be insulated from the first power plane 110 by a sidewall spacer 632, or a dielectric liner, of dielectric material.

In yet another embodiment, the semiconductor structure 30 may include a TPPV 533 that extends vertically through the first and the second power plane 110 and 120, from a level above the second top transistor to a level below the second bottom transistor in the second transistor cell 2. The TPPV 533 may include a bottom portion 5331 and a top portion 5332 and a width of the TPPV 533 may have a discontinuity at an interface between the bottom portion 5331 and the top portion 5332. Like other TPPV, the TPPV 533 may be insulated from the first and the second power plane 110 and 120 by one or more sidewall spacers and/or dielectric liners and may be formed away, or separated, from the S/D region 202 of the top transistor and away from the S/D region 302 of the bottom transistor in the transistor cell 2.

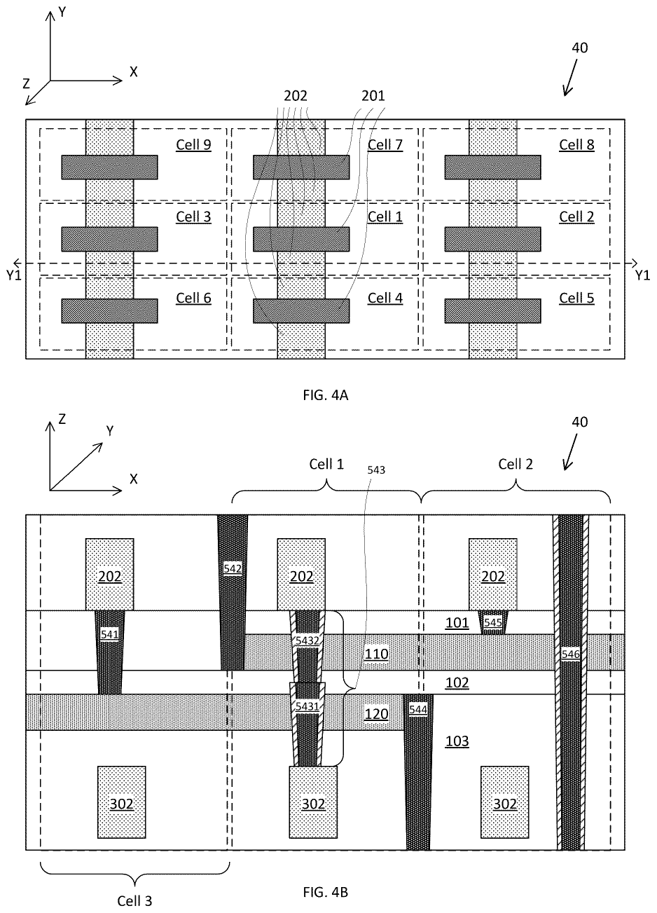

FIG. 4A is a demonstrative illustration of a simplified top view and FIG. 4B is a demonstrative illustration of a cross-sectional view of a semiconductor structure 40 according to a further embodiment of present invention. More specifically, FIG. 4B illustrates a cross-sectional view of the semiconductor structure 40 with a cross-section made along a dashed line Y1-Y1, as being indicated in FIG. 4A, across S/D regions of transistors in transistor cells 1, 2, and 3 in a direction along width of gate of the transistors.

Similar to the semiconductor structure 10, 20, and 30, the semiconductor structure 40 includes a first power plane 110 and a second power plane 120 between at least two top transistors and two bottom transistors respectively. For example, the first power plane 110 may expand across the first and second transistor cells 1 and 2, and the second power plane 120 may expand the first and third transistor cells 1 and 3. In other words, the first power plane 110 vertically overlaps with the second power plane 120 in the first transistor cell 1 and does not vertically overlap with the second power plane 120 in the second transistor cell 2 and in the third transistor cell 3. The second bottom transistor in the second transistor cell 2 is directly underneath, without the second power plane 120 in-between, the first power plane 110 and the third top transistor in the third transistor cell 3 is directly above, with the first power plane 110 in-between, the second power plane 120.

In one embodiment, a S/D region 202 of the third top transistor in the third transistor cell 3 may be conductively connected to the second power plane 120 through a power via 541 which does not go through the first power plane 110. Therefore, no sidewall spacer of dielectric material is needed to insulate the power via 541 from the first power plane 110. In another embodiment, a S/D region 202 of the second top transistor in the second transistor cell 2 may be conductively connected to the first power plane 110 through a power via 545. In yet another embodiment, the semiconductor structure 40 may include a TPPV 543 that includes a bottom portion 5431 and a top portion 5432 on top of the bottom portion 5431. The TPPV 543 connects a S/D region 202 of the first top transistor with a S/D region 302 of the first bottom transistor in the first transistor cell 1. The TPPV 543 has a sidewall that changes discontinuously from the bottom portion 5431 to the top portion 5432.

According to one embodiment, the semiconductor structure 40 may further include a first routing via 542 that connects the first power plane 110 with a back-end-of-line (BEOL) structure above the first and the second top transistor of the first and the second transistor cell 1 and 2. The first routing via 542 may be formed at a boundary between transistor cells such as, for example, between the first transistor cell 1 and the third transistor cell 3. Furthermore, the first routing via 542 may contact the first power plane 110 at an edge of the first power plane 110. Similarly, the semiconductor structure 40 may also include a second routing via 544 that connects the second power plane 120 with a backside back-end-of-line (BBEOL) structure below the first and the third bottom transistor of the first and the third transistor cell 1 and 3. The second routing via 544 may be formed at a boundary between transistor cells such as, for example, between the second transistor cell 2 and the third transistor cell 3 and contacts the second power plane 120 at an edge of the second power plane 120.

According to one embodiment, the first, second, and third top transistors and the first, second, and third bottom transistors may together form a static-random-access memory (SRAM), and the first power plane 110 is connected, through the first routing via 542, to a VDD of the SRAM and the second power plane 120 is connected, through the second routing via 544, to a VSS of the SRAM. However, embodiments of present invention are not limited in this aspect and other top and/or bottom transistors may be used to form the SRAM.

The semiconductor structure 40 may further include a TPPV 546 that is formed in the second transistor cell 2 and extends vertically from a level above the second top transistor to a level below the second bottom transistor. The TPPV 546 may be used in interconnecting devices situated above and below the semiconductor structure 40.

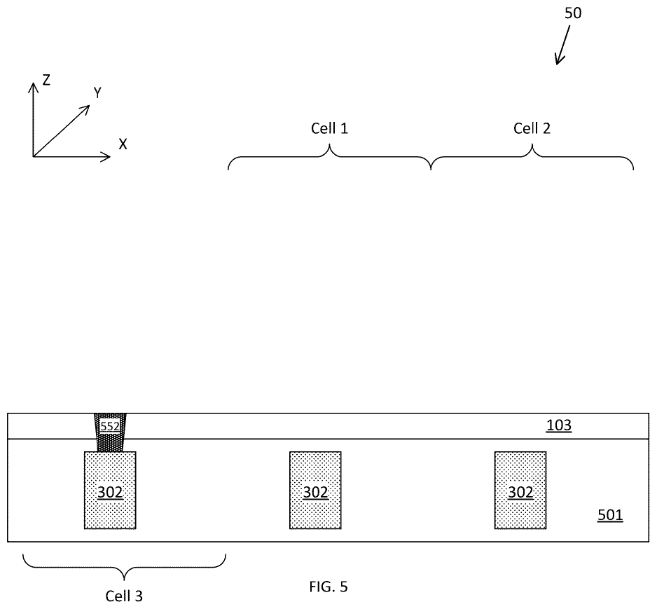

FIG. 5 is a demonstrative illustration of cross-sectional view of a semiconductor structure at a step of manufacturing thereof according to one embodiment of present invention. More particularly, embodiments of present invention provide forming a semiconductor structure 50 by forming a plurality of bottom transistors in a bottom semiconductor layer 501. The plurality of bottom transistors may include their respective metal gate and S/D regions, for example, such as S/D regions 302. The S/D regions 302 may be formed in multiple transistor cells such as a first transistor cell 1, a second transistor cell 2, and a third transistor cell 3. Next, embodiments of present invention provide forming a bottom dielectric plane 103, such as a dielectric layer, on top of the bottom semiconductor layer 501 covering the first, second, and third bottom transistors. In one embodiment, a power via 552 may next be formed that goes through the bottom dielectric plane 103 and contacts the S/D region 302 of the bottom transistor in the third transistor cell 3.

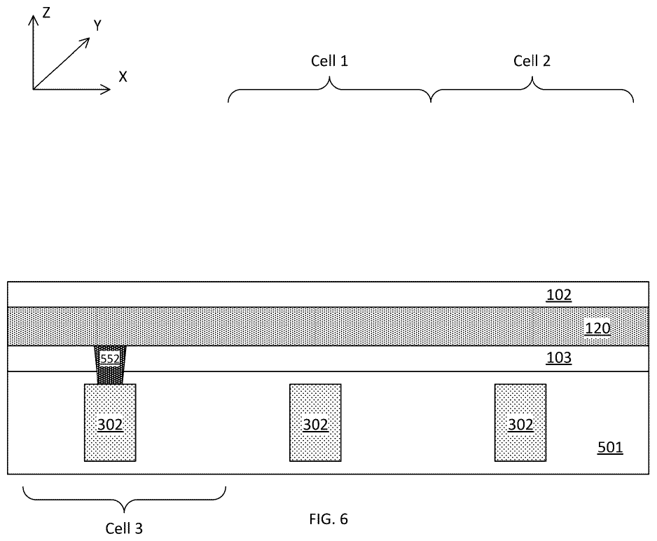

FIG. 6 is a demonstrative illustration of cross-sectional view of a semiconductor structure at a step of manufacturing thereof, following the step illustrated in FIG. 5, according to one embodiment of present invention. More particularly, embodiments of present invention provide forming a second power plane 120 on top of the bottom dielectric plane 103 and a middle dielectric plane 102 on top of the second power plane 120. The second power plane 120 may be a layer of conductive material such as, for example, copper (Cu), aluminum (Al), tungsten (W), etc., and may be formed on top of the bottom dielectric plane 103 through an atomic-layer-deposition (ALD) process, a chemical-vapor-deposition (CVD) process, or a physical-vapor-deposition (PVD) process. The second power plane 120 may be formed to have a thickness ranging from about 5 nm to about 50 nm, or even less than 5 nm when 2D material (i.e., crystalline solids consisting of a single layer of atoms) such as graphene is used for forming power plane. The second power plane 120 may be formed, for example through a lithographic patterning process, to cover at least two neighboring cells but in some embodiment may be formed to cover only some of the transistor cells such as, for example, the first transistor cell 1 and the third transistor cell 3, leaving the second transistor cell 2 uncovered by the second power plane 120.

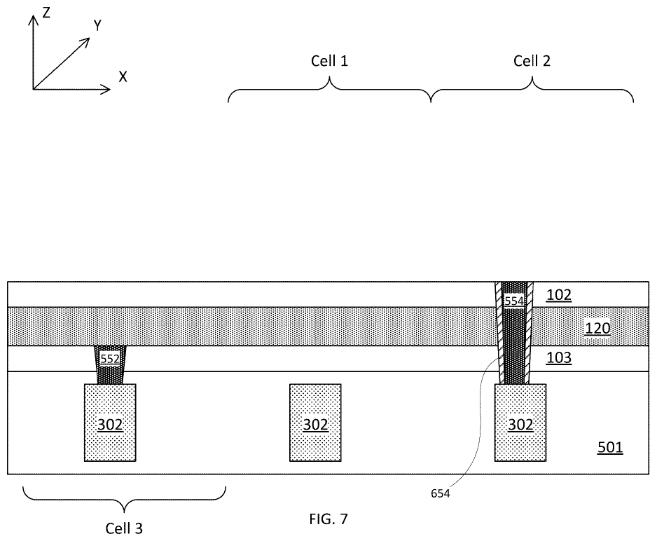

FIG. 7 is a demonstrative illustration of cross-sectional view of a semiconductor structure at a step of manufacturing thereof, following the step illustrated in FIG. 6, according to one embodiment of present invention. More particularly, embodiments of present invention provide forming one or more through-power-plane-vias that go through openings in the second power plane 120 and contact the bottom transistors such as contact the S/D regions 302 of the bottom transistors. For example, a TPPV 554 may be formed that goes through the middle dielectric plane 102 and the second power plane 120, via openings formed respectively in the middle dielectric plane 102 and the second power plane 120. The TPPV 554 may be insulated from the second power plane 120, by a sidewall spacer 654 formed at sidewalls of the openings and contact the S/D region 302 in the second transistor cell 2.

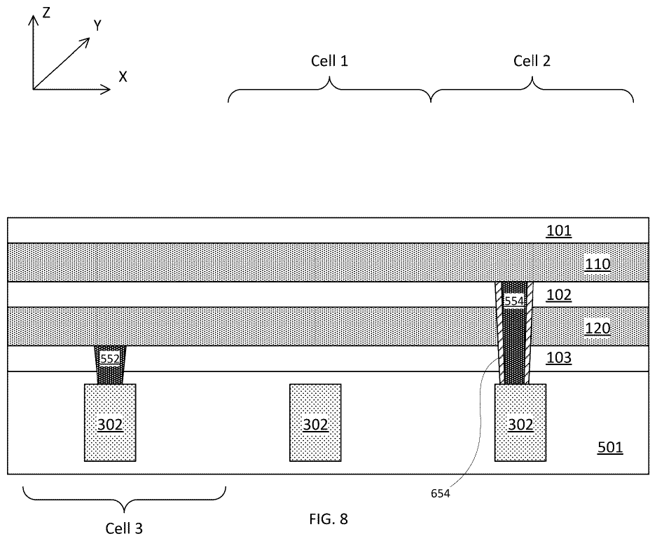

FIG. 8 is a demonstrative illustration of cross-sectional view of a semiconductor structure at a step of manufacturing thereof, following the step illustrated in FIG. 7, according to one embodiment of present invention. More particularly, embodiments of present invention provide forming a first power plane 110 on top of the middle dielectric plane 102, and a top dielectric plane 101, such as a dielectric layer, on top of the first power plane 110. Similar to the second power plane 120, the first power plane 110 may be formed through an ALD process, a CVD process, or a PVD process to have a thickness ranging from about 5 nm to about 90 nm, or even less than 5 nm when a suitable 2D material is used. The first power plane 110 may expand at least two neighboring transistor cells but, in one embodiment, may not expand across all of the transistor cells. For example, the first power plane 110 may expand across the first transistor cell 1 and the second transistor cell 2 and may not expand across the third transistor cell 3.

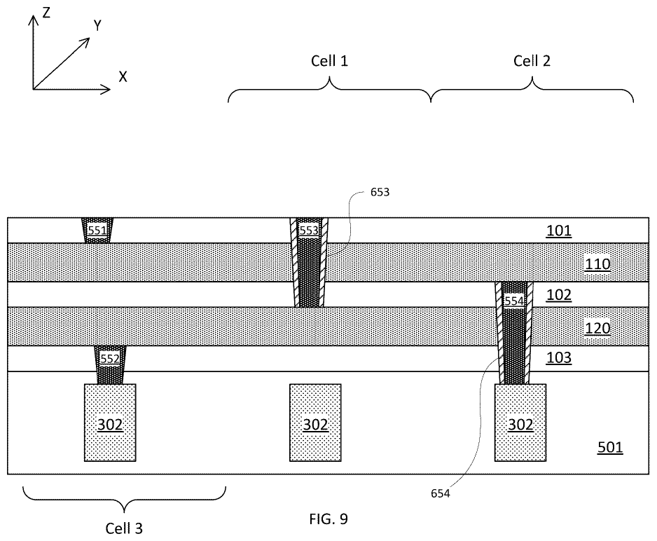

FIG. 9 is a demonstrative illustration of cross-sectional view of a semiconductor structure at a step of manufacturing thereof, following the step illustrated in FIG. 8, according to one embodiment of present invention. More particularly, embodiments of present invention provide forming one or more power vias or TPPVs contacting the first and/or the second power plane 110 and 120. The one or more power vias or TPPVs may be used to connect one or more top transistors with either the first or the second power plane 110 and 120. For example, a power via 551 may be formed in the top dielectric plane 101 to be in contact with the first power plane 110. Further for example, a TPPV 553 may be formed that goes through openings in the top dielectric plane 101 and the first power plane 110 to be in contact with the second power plane 120. A sidewall spacer 653 may be formed in the openings in the top dielectric plane 101 and the first power plane 110. The sidewall spacer 653, such as a dielectric liner, may insulate the TPPV 553 from the first power plane 110.

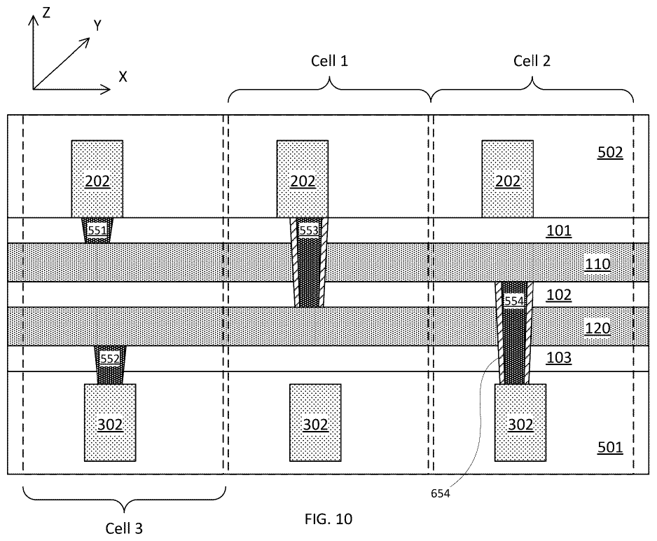

FIG. 10 is a demonstrative illustration of cross-sectional view of a semiconductor structure at a step of manufacturing thereof, following the step illustrated in FIG. 9, according to one embodiment of present invention. More particularly, embodiments of present invention provide forming a top semiconductor layer 502 on top of the top dielectric plane 101 and a plurality of top transistors inside the top semiconductor layer 502. The top transistors may include S/D regions 202 and the S/D regions 202 may be formed to be in contact with, for example, the power via 551 and the TPPV 553.

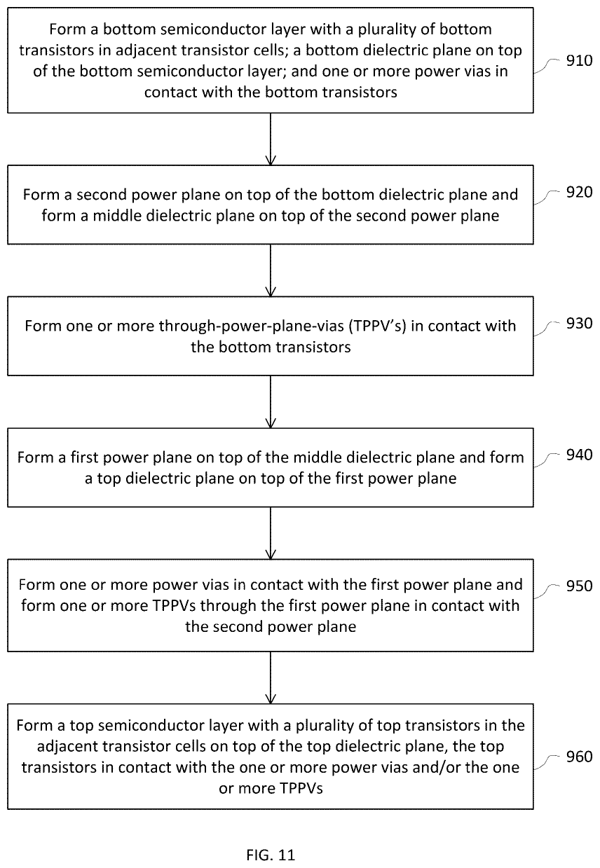

FIG. 11 is a demonstrative illustration of a flow-chart of a method of manufacturing a semiconductor structure according to embodiments of present invention. The method includes (910) forming a bottom semiconductor layer with a plurality of bottom transistors in adjacent transistor cells; a bottom dielectric plane on top of the bottom semiconductor layer; and one or more power vias in contact with the bottom transistors; (920) forming a second power plane on top of the bottom dielectric plane and a middle dielectric plane on top of the second power plane; (930) forming one or more through-power-plane-vias (TPPV's) in contact with the bottom transistors; (940) forming a first power plane on top of the middle dielectric plane and a top dielectric plane on top of the first power plane; (950) forming one or more power vias in contact with the first power plane and one or more TPPVs through the first power plane in contact with the second power plane; and (960) forming a top semiconductor layer with a plurality of top transistors in the adjacent transistor cells on top of the top dielectric plane, the top transistors in contact with the one or more power vias and/or the one or more TPPVs.

Various examples may possibly be described by one or more of the following features in the following numbered clauses:
Clause 1: A semiconductor structure comprising: a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to the first transistor cell; and at least one power plane between the first top transistor and the first bottom transistor and between the second top transistor and the second bottom transistor.
Clause 2: The semiconductor structure of clause 1, wherein the at least one power plane is a first power plane, further comprising a second power plane underneath the first power plane and between the second top transistor and the second bottom transistor, the second power plane being parallel to the first power plane.
Clause 3: The semiconductor structure of clause 2, further comprising a through-power-plane-via (TPPV) extending vertically through the first and the second power plane, from a level above the second top transistor to a level below the second bottom transistor, the TPPV being insulated from the first and the second power plane by a sidewall spacer.
Clause 4: The semiconductor structure of clause 3, wherein the second top transistor does not vertically align with the second bottom transistor and the TPPV is formed within the second transistor cell but away from the second top transistor and away from the second bottom transistor.
Clause 5: The semiconductor structure of clause 2, wherein the first top transistor is conductively connected to the first power plane by a power via.
Clause 6: The semiconductor structure of clause 2, wherein the first top transistor is conductively connected to the second power plane by a power via, and the power via extends through an opening in the first power plane and is insulated from the first power plane by a sidewall spacer.
Clause 7: The semiconductor structure of clause 2, wherein the first top transistor is conductively connected to the first bottom transistor by a power via, and the power via extends through an opening in the first power plane and through an opening in the second power plane and is insulated from the first and the second power plane by a sidewall spacer.
Clause 8: The semiconductor structure of clause 2, further comprising a middle dielectric plane between the first power plane and the second power plane, and the middle dielectric plane insulates the first power plane from the second power plane.
Clause 9: The semiconductor structure of clause 2, further comprising a top dielectric plane directly on top of the first power plane and underneath the first and the second top transistor.
Clause 10: The semiconductor structure of clause 2, further comprising a bottom dielectric plane on top of the first and the second bottom transistor and directly underneath the first power plane.
Clause 11: A semiconductor structure comprising: a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to a first side of the first transistor cell; a third stack of transistors in a third transistor cell, the third stack of transistors including a third top transistor and a third bottom transistor, the third transistor cell being adjacent to a second side of the first transistor cell, the second side opposing the first side; a first power plane between the first top transistor and the first bottom transistor and between the second top transistor and the second bottom transistor; and a second power plane between the first top transistor and the first bottom transistor and between the third top transistor and the third bottom transistor, wherein the second bottom transistor is underneath the first power plane and the third top transistor is above the second power plane.
Clause 12: The semiconductor structure of clause 11, wherein the first and the second power plane vertically overlap in the first transistor cell and do not vertically overlap in the second and third transistor cell.
Clause 13: The semiconductor structure of clause 11, wherein the first and the second power plane horizontally extend across the first, the second, and the third transistor cell.
Clause 14: A semiconductor structure comprising: a first stack of transistors in a first transistor cell, the first stack of transistors including a first top transistor and a first bottom transistor; a second stack of transistors in a second transistor cell, the second stack of transistors including a second top transistor and a second bottom transistor, the second transistor cell being adjacent to the first transistor cell; a third stack of transistors in a third transistor cell, the third stack of transistors including a third top transistor and a third bottom transistor, the third transistor cell being adjacent to the first transistor cell; a first power plane between the first top transistor and the first bottom transistor and between the second top transistor and the second bottom transistor; and a second power plane between the first top transistor and the first bottom transistor and between the third top transistor and the third bottom transistor.
Clause 15: The semiconductor structure of clause 14, further comprising a middle dielectric plane between the first power plane and the second power plane, wherein the first and the second power plane vertically overlap at least in the first transistor cell.
Clause 16: The semiconductor structure of clause 14, wherein the first power plane is connected to a VDD and the second power plane is connected to a VSS of a static-random-access memory (SRAM) device.
Clause 17: The semiconductor structure of clause 14, wherein the first power plane is connected to a back-end-of-line (BEOL) structure above the first and the second top transistor through a first routing via at a boundary between the first transistor cell and the third transistor cell.
Clause 18: The semiconductor structure of clause 17, wherein the second power plane is connected to a backside back-end-of-line (BBEOL) structure below the first and the third bottom transistor through a second routing via at a boundary between the first transistor cell and the second transistor cell.
Clause 19: The semiconductor structure of clause 14, wherein a source/drain region of the first top transistor is conductively connected to a source/drain region of the first bottom transistor through a through-power-plane-via (TPPV), the TPPV has a bottom portion and a top portion on top of the bottom portion and a sidewall that changes discontinuously from the bottom portion to the top portion.
Clause 20: The semiconductor structure of clause 14, wherein a source/drain region of the second top transistor is conductively connected to the first power plane by a power via.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first stack of transistors in a first transistor cell, the first stack of transistors including a first top transistor and a first bottom transistor;
a second stack of transistors in a second transistor cell, the second stack of transistors including a second top transistor and a second bottom transistor, the second transistor cell being adjacent to the first transistor cell; and
at least one power plane between the first top transistor and the first bottom transistor and between the second top transistor and the second bottom transistor.

2. The semiconductor structure of claim 1, wherein the at least one power plane is a first power plane, further comprising a second power plane underneath the first power plane and between the second top transistor and the second bottom transistor, the second power plane being parallel to the first power plane.

3. The semiconductor structure of claim 2, further comprising a through-power-plane-via (TPPV) extending vertically through the first and the second power plane, from a level above the second top transistor to a level below the second bottom transistor, the TPPV being insulated from the first and the second power plane by a sidewall spacer.

4. The semiconductor structure of claim 3, wherein the second top transistor does not vertically align with the second bottom transistor and the TPPV is formed within the second transistor cell but away from the second top transistor and away from the second bottom transistor.

5. The semiconductor structure of claim 2, wherein the first top transistor is conductively connected to the first power plane by a power via.

6. The semiconductor structure of claim 2, wherein the first top transistor is conductively connected to the second power plane by a power via, and the power via extends through an opening in the first power plane and is insulated from the first power plane by a sidewall spacer.

7. The semiconductor structure of claim 2, wherein the first top transistor is conductively connected to the first bottom transistor by a power via, and the power via extends through an opening in the first power plane and through an opening in the second power plane and is insulated from the first and the second power plane by a sidewall spacer.

8. The semiconductor structure of claim 2, further comprising a middle dielectric plane between the first power plane and the second power plane, and the middle dielectric plane insulates the first power plane from the second power plane.

9. The semiconductor structure of claim 2, further comprising a top dielectric plane directly on top of the first power plane and underneath the first and the second top transistor.

10. The semiconductor structure of claim 2, further comprising a bottom dielectric plane on top of the first and the second bottom transistor and directly underneath the first power plane.

11. A semiconductor structure comprising:
a first stack of transistors in a first transistor cell, the first stack of transistors including a first top transistor and a first bottom transistor;
a second stack of transistors in a second transistor cell, the second stack of transistors including a second top transistor and a second bottom transistor, the second transistor cell being adjacent to a first side of the first transistor cell;
a third stack of transistors in a third transistor cell, the third stack of transistors including a third top transistor and a third bottom transistor, the third transistor cell being adjacent to a second side of the first transistor cell, the second side opposing the first side;
a first power plane between the first top transistor and the first bottom transistor and between the second top transistor and the second bottom transistor; and
a second power plane between the first top transistor and the first bottom transistor and between the third top transistor and the third bottom transistor,
wherein the second bottom transistor is underneath the first power plane and the third top transistor is above the second power plane.

12. The semiconductor structure of claim 11, wherein the first and the second power plane vertically overlap in the first transistor cell and do not vertically overlap in the second and third transistor cell.

13. The semiconductor structure of claim 11, wherein the first and the second power plane horizontally extend across the first, the second, and the third transistor cell.

14. A semiconductor structure comprising:
a first stack of transistors in a first transistor cell, the first stack of transistors including a first top transistor and a first bottom transistor;
a second stack of transistors in a second transistor cell, the second stack of transistors including a second top transistor and a second bottom transistor, the second transistor cell being adjacent to the first transistor cell;
a third stack of transistors in a third transistor cell, the third stack of transistors including a third top transistor and a third bottom transistor, the third transistor cell being adjacent to the first transistor cell;
a first power plane between the first top transistor and the first bottom transistor and between the second top transistor and the second bottom transistor; and
a second power plane between the first top transistor and the first bottom transistor and between the third top transistor and the third bottom transistor.

15. The semiconductor structure of claim 14, further comprising a middle dielectric plane between the first power plane and the second power plane, wherein the first and the second power plane vertically overlap at least in the first transistor cell.

16. The semiconductor structure of claim 14, wherein the first power plane is connected to a VDD and the second power plane is connected to a VSS of a static-random-access memory (SRAM) device.

17. The semiconductor structure of claim 14, wherein the first power plane is connected to a back-end-of-line (BEOL) structure above the first and the second top transistor through a first routing via at a boundary between the first transistor cell and the third transistor cell.

18. The semiconductor structure of claim 17, wherein the second power plane is connected to a backside back-end-of-line (BBEOL) structure below the first and the third bottom transistor through a second routing via at a boundary between the first transistor cell and the second transistor cell.

19. The semiconductor structure of claim 14, wherein a source/drain region of the first top transistor is conductively connected to a source/drain region of the first bottom transistor through a through-power-plane-via (TPPV), the TPPV has a bottom portion and a top portion on top of the bottom portion and a sidewall that changes discontinuously from the bottom portion to the top portion.

20. The semiconductor structure of claim 14, wherein a source/drain region of the second top transistor is conductively connected to the first power plane by a power via.
